(19) United States
(12) Patent Application Publication
(10) Pub. No.: US 2025/0290976 A1
(43) Pub. Date: Sep. 18, 2025

(54) CHIP PACKAGE STRUCTURE, FABRICATION METHOD AND MEMORY SYSTEM

(71) Applicant: YANGTZE MEMORY TECHNOLOGIES CO., LTD., Wuhan (CN)

(72) Inventors: Shu WU, Wuhan (CN); WenBin ZHOU, Wuhan (CN); Wei LIU, Wuhan (CN); ZongLiang HUO, Wuhan (CN)

(21) Appl. No.: 19/072,565

(22) Filed: Mar. 6, 2025

(30) Foreign Application Priority Data
Mar. 12, 2024 (CN) 2024102855968

(51) Int. Cl. G01R 31/28; H01L 23/48; H01L 25/07

(52) U.S. Cl. CPC G01R 31/2896; H01L 25/074; H01L 23/481

(57) ABSTRACT

A chip package structure may include a stack structure, routing layer, protective layer and a plurality of first filling blocks. The stack structure may include a plurality of dies stacked. The routing layer may be over a side of the stack structure. A plurality of interconnect structures may be disposed in the routing layer, and any two of the dies in the stack structure may be connected with each other through at least one interconnect structure. The protective layer may be over a side of the routing layer away from the stack structure. One first filling block may be over a side of one interconnect structure away from the stack structure, and the first filling block may extend through the protective layer along a stacking direction.

### CROSS-REFERENCE TO RELATED APPLICATIONS

This disclosure claims the benefit of priority to Chinese Patent Application No. 2024102855968, filed on Mar. 12, 2024, which is incorporated herein by reference in its entirety.

### TECHNICAL FIELD

The present disclosure relates to the field of chip package technology, and particularly to a chip package structure, a fabrication method thereof, a memory system, and an electronic apparatus.

### BACKGROUND

Currently, with increasing demands on memory bandwidth in applications such as high-performance computing, AI, 5G, etc., a high bandwidth memory (HBM) module structure implemented by vertically stacking multiple layers of dynamic random access memories (DRAMs) has become a mainstream solution.

### SUMMARY

In an aspect, a chip package structure is provided. The chip package structure may include a stack structure, a routing layer, a protective layer and a plurality of first filling blocks.

The stack structure may include a plurality of dies that are stacked.

The routing layer may be located over a side of the stack structure. A plurality of interconnect structures may be disposed in the routing layer, and any two of the plurality of dies in the stack structure are connected with each other through at least one of the plurality of interconnect structures.

The protective layer may be located over a side of the routing layer away from the stack structure.

One of the plurality of first filling blocks may be located over a side of one of plurality of the interconnect structures away from the stack structure, and the plurality of first filling blocks extend through the protective layer along a stacking direction.

In some implementations, the plurality of dies comprise at least one first die and at least one second die.

The interconnect structure connected with the second die may be broken off, and along the stacking direction, a broken-off region of the interconnect structure may overlap the first filling block over a side of the interconnect structure.

In some implementations, the second die may include a defective die, and the first die comprises a qualified die.

In some implementations, the interconnect structure may include a first conductive pad and at least two connection structures. One end of each of the at least two connection structures may be connected with the first conductive pad, and the other end of each of the at least two connection structures may be connected with different ones of the dies respectively.

The first conductive pad of the interconnect structure connected with the second die may be broken off.

In some implementations, the first conductive pad of the interconnect structure connected with the second die may have a trace of breaking off by laser ablation.

In some implementations, an area of one end of the first filling block close to the routing layer may be greater than or equal to an area of the broken-off region of the interconnect structure.

In some implementations, the area of one end of the first filling block close to the routing layer may be less than the area of one end of the first filling block away from the routing layer.

In some implementations, the chip package structure may further include a test structure and a second filling block.

The test structure may be located in the routing layer and connected with at least one of the plurality of dies.

The second filling block may be located over a side of the test structure away from the stack structure and may extend through the protective layer along the stacking direction.

In some implementations, the chip package structure may further include a package layer covering the stack structure, the routing layer and the protective layer.

Part of material of the package layer may form the first filling block and the second first filling block.

In another aspect, a fabrication method of a chip package structure is provided. The fabrication method may include: stacking a plurality of dies to form a stack structure; forming a routing layer over a side of the stack structure, wherein a plurality of interconnect structures are formed in the routing layer, and any two of the plurality of dies in the stack structure are connected with each other through at least one of the plurality of interconnect structures; forming a protective layer over a side of the routing layer away from the stack structure; forming a plurality of first openings in the protective layer, wherein one of the plurality of first openings is located over a side of one of the plurality of interconnect structures away from the stack structure, and the plurality of first openings extend through the protective layer along a stacking direction; detecting the plurality of dies in the stack structure; and based on a defective die in the stack structure, breaking off the interconnect structure connected with the defective die via the first opening.

In some implementations, the interconnect structure connected with the defective die may be broken off by a laser ablation process.

In some implementations, the fabrication method of the chip package structure may further include: forming a test structure in the routing layer, wherein the test structure is connected with at least one of the plurality of dies; and forming a second opening in the protective layer, wherein the second opening is located over a side of the test structure away from the stack structure, and extends through the protective layer along the stacking direction.

The detecting the plurality of dies in the stack structure may include: detecting, by the test structure, the dies connected with the test structure via the second opening.

In some implementations, the fabrication method of the chip package structure may further include: forming a package layer. The package layer covers the stack structure, the routing layer and the protective layer.

Part of material of the package layer fills the first opening to form a first filling block, and fills the second opening to form a second filling block.

In some implementations, the interconnect structure may include a first conductive pad and at least two connection structures. One end of each of the connection structures may be connected with the first conductive pad, and the other end of each of the connection structures may be connected with different ones of the dies in the stack structure.

The breaking off the interconnect structure connected with the defective die may include: breaking off the first conductive pad of the interconnect structure connected with the defective die.

In another aspect, a memory system is provided. The memory system may include the above-mentioned chip package structure and a controller. The controller is connected with the chip package structure.

In another aspect, an electronic apparatus is provided. The electronic apparatus may include a processor and the above-mentioned memory system. The processor is coupled with the memory system.

### BRIEF DESCRIPTION OF THE DRAWINGS

In order to illustrate the technical solution in the present disclosure more clearly, the drawings to be used in some implementations of the present disclosure will be briefly introduced below. Apparently, the drawings in the following description are only drawings of some implementations of the present disclosure. Those of ordinary skills in the art may also obtain other drawings according to these drawings. In addition, the drawings in the following description may be regarded as schematic diagrams, instead of limitations to actual size of products, actual process flow of methods, actual timing of signals, etc. involved in the implementations of the present disclosure.

FIG. 1 is a structural diagram of an electronic apparatus provided by some implementations of the present disclosure;

FIG. 2A is a structural diagram of a memory system provided by some implementations of the present disclosure;

FIG. 2B is another structural diagram of a memory system provided by some implementations of the present disclosure;

FIG. 3 is a structural diagram of an AA region of the chip package structure in FIG. 2B;

FIG. 4 is a structural plan view of the routing layer in FIG. 3;

FIG. 5 is another structural diagram of an AA region of the chip package structure in FIG. 2B;

FIG. 6 is yet another structural diagram of an AA region of the chip package structure in FIG. 2B;

FIG. 7 is a structural plan view of the routing layer in FIG. 6;

FIG. 8 is another structural diagram of an AA region of the chip package structure in FIG. 2B;

FIG. 9 is a structural diagram of a partial region of a chip package structure provided by some implementations of the present disclosure;

FIG. 10 is a flow diagram of a fabrication method of a chip package structure provided by some implementations of the present disclosure;

FIG. 11 is a structural diagram corresponding to operation S1 in the fabrication method of the chip package structure provided by FIG. 10;

FIG. 12 is a structural diagram corresponding to operation S2 and operation S7 in the fabrication method of the chip package structure provided by FIG. 10;

FIG. 13 is a structural diagram of a BB region in FIG. 12;

FIG. 14 is a structural diagram corresponding to operation S3, operation S4 and operation S8 in the fabrication method of the chip package structure provided by FIG. 10;

FIG. 15 is a structural diagram of a BB region in FIG. 14;

FIG. 16 is a structural diagram corresponding to operation S6 in the fabrication method of the chip package structure provided by FIG. 10; and

FIG. 17 is a structural diagram corresponding to operation S9 in the fabrication method of the chip package structure provided by FIG. 10.

### DETAILED DESCRIPTION

The technical solutions in some examples of the present disclosure will be described below clearly and completely in conjunction with the drawings. Apparently, the examples described are only part of, but not all of, the examples of the present disclosure. All other examples obtained by those of ordinary skills in the art based on the examples provided by the present disclosure should fall in the scope of protection of the present disclosure.

In the description of the present disclosure, it is to be understood that the terms “center”, “upper”, “lower”, “front”, “rear”, “left”, “right”, “vertical”, “horizontal”, “top”, “bottom”, “inner”, “outer”, etc. indicate orientations or position relationships that are based on the orientations or position relationships as shown in the drawings, and are only intended to facilitate description of the present disclosure and to simplify the description, instead of indicating or implying that a device or an element indicated must have a specific orientation or be configured and operated in a specific orientation, and thus cannot be understood as limiting the present disclosure.

Unless otherwise specified in the context, throughout the specification and the claims, the term “comprise” is interpreted as an open and inclusive meaning, e.g., “including, but not limited to”. In the description of the specification, the terms “one example”, “some examples”, “an example”, or “in an example”, etc. are intended to indicate that particular features, structures, materials, or characteristics related to the example are included in at least one example of the present disclosure. The schematic representation of the above terms may not necessarily refer to the same example. Furthermore, these particular features, structures, materials, or characteristics may be included in any one or more examples in any suitable manner.

In the following, the terms “first” and “second” are only for the purpose of description, and cannot be construed as indicating or implying relative importance or implicitly indicating the number of indicated technical features. Thus, features defined by “first” and “second” may explicitly or implicitly comprise one or more of such features. In the description of the examples of the present disclosure, “a plurality of” means two or more, unless otherwise stated.

In the description of some examples, the expressions “coupled” and “connected” and derivatives thereof may be used. For example, the term “connected” may be used in the description of some examples to indicate that two or more components have direct physical contact or electrical contact with each other. For another example, the term “coupled” may be used in the description of some examples to indicate that two or more components have direct physical contact or electrical contact. However, the term “coupled” may also mean that two or more components have no direct contact with each other, but still cooperate or interact with each other. The examples disclosed herein are not necessarily limited to the content herein.

The meaning of “on”, “above”, and “over” in the contents of the present disclosure should be interpreted in the broadest manner such that “on” not only means “directly on something” but also comprises the meaning of “on something” with an intermediate feature or layer therebetween, and that “above” or “over” not only means “above” or “over” something but also comprises the meaning of “above” or “over” something with no intermediate feature or layer therebetween (e.g., directly on something).

Example implementations are described herein with reference to a cross-sectional view and/or a planar view that are used as idealized example drawings. In the drawings, thicknesses of layers and areas of regions are exaggerated for clarity. Thus, changes in shapes relative to the drawings caused by, for example, manufacturing technology and/or tolerance, may be contemplated. Therefore, the example implementations should not be interpreted as being limited to the shapes of regions shown herein, but rather comprise shape deviations caused by, for example, manufacturing. For example, an etching region shown as a rectangle will typically have a curved feature. Therefore, the regions shown in the drawings are essentially schematic, and their shapes are neither intended to show actual shapes of regions of an apparatus, nor intended to limit the scope of the example implementations.

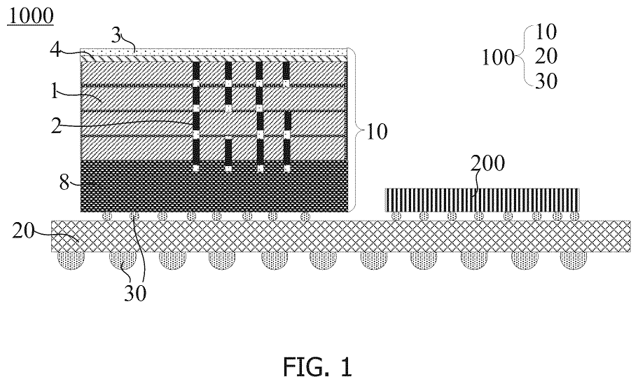

As shown in FIG. 1, some examples of the present disclosure provide an electronic apparatus 1000. The electronic apparatus 1000 comprises, but is not limited to, any one of a mobile phone, a tablet computer, a laptop computer, a television, a Personal Digital Assistant (PDA), an Ultra-Mobile Personal Computer (UMPC), a netbook, a wearable apparatus (e.g., a smart watch, a smart bracelet, and smart glasses), and the like. The type of the electronic apparatus is not limited by the examples of the present disclosure.

In some examples, with continued reference to FIG. 1, the electronic apparatus 1000 comprises a memory system 100 and a processor 200. The processor 200 is coupled with the memory system 100 to interact with the memory system 100.

In an example, the processor 200 may be a central processing unit (CPU), or may be another general-purpose processor, a graphics processing unit (GPU), a system-on-chip (SoC), a digital signal processor (DSP), an application-specific integrated circuit (ASIC), a field-programmable gate array (FPGA) or another programmable logic device, a discrete gate or transistor logic device, a discrete hardware component, etc. The general-purpose processor may be a microprocessor, or the processor may be any other suitable processor or the like.

The above-mentioned memory system 100 is described below in detail.

The above-mentioned memory system 100 may be integrated into a memory card. The memory card comprises, for example, any one of a PC card (Personal Computer Memory Card International Association, PCMCIA), a Compact Flash (CF) card, a Smart Media (SM) card, a memory stick, a Multimedia Card (MMC), a Secure Digital Memory Card (SD) card, and a UFS.

The memory system 100 may be further integrated into various types of memory apparatuses, for example, be included in the same package (e.g., a Universal Flash Storage (UFS) package or an embedded Multi-Media Card (eMMC) package). For example, the memory system 100 can be applied to and packaged into different types of electronic products, for example, a mobile phone (e.g., a cell phone), a desktop computer, a tablet computer, a laptop computer, a server, a vehicle apparatus, a game console, a printer, a positioning apparatus, a wearable apparatus, a smart sensor, a mobile power supply, a virtual reality (VR) apparatus, an augmented reality (AR) apparatus or any other suitable electronic apparatuses having memories therein.

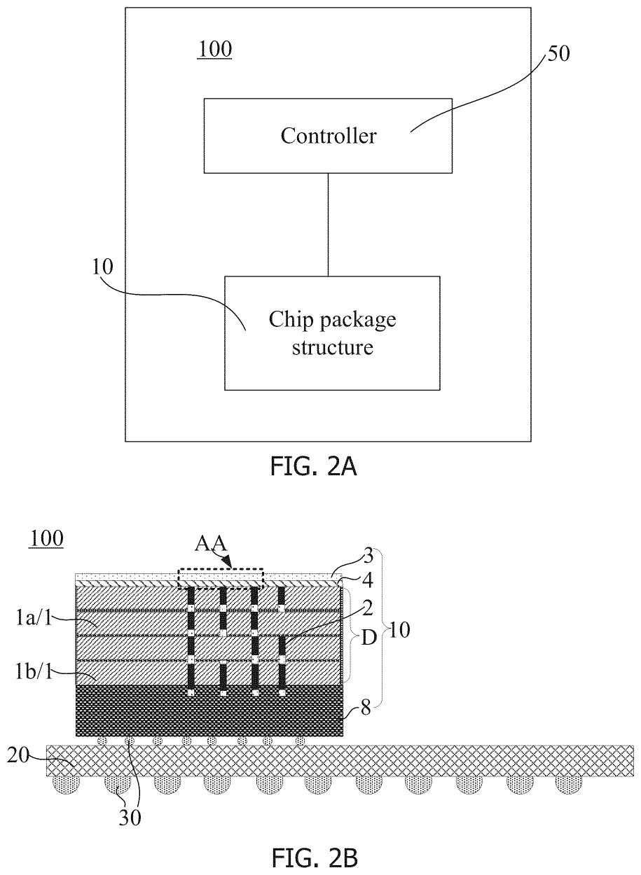

In some examples, as shown in FIG. 2A, FIG. 2A is a structural diagram of the memory system 100 provided by some examples of the present disclosure. The memory system 100 comprises a chip package structure 10 and a controller 50. The controller 50 is electrically connected with the chip package structure 10, and may control the chip package structure 10 to store data.

In an example, the controller 50 may be integrated with the chip package structure 10, or may be disposed outside the chip package structure 10, and is electrically connected with the chip package structure 10 through leads or a transfer film layer.

In some examples, the controller 50 in the memory system 100 is configured for operating in a low duty-cycle environment, such as SD cards, CF cards, Universal Serial Bus (USB) flash drives, or other media for use in electronic apparatuses such as personal computers, digital cameras, mobile phones, etc.

In some other examples, the controller 50 is configured for operating in high duty-cycle environments like SSDs or eMMCs used as data memories for mobile apparatuses, such as smartphones, tablet computers, notebook computers, etc., and enterprise memory arrays.

In some examples, the controller 50 may be configured to manage data stored in the chip package structure 10 and communicate with an external apparatus (e.g., a host).

In some examples, the controller 50 may be further configured to control operations of the chip package structure 10, such as read, erase and program operations.

In some examples, the controller 50 may be further configured to manage various functions with respect to data stored or to be stored in the chip package structure 10, including at least one of bad-block management, garbage collection, logical-to-physical address conversion, and wear leveling.

In some examples, the controller 50 is further configured to process error correction codes with respect to the data read from or written to the chip package structure 10.

Of course, the controller 50 may also perform any other suitable functions, such as formatting the chip package structure 10. For example, the controller 50 may communicate with an external apparatus (e.g., a host) through at least one of various interface protocols.

It is to be noted that, the interface protocols include at least one of a USB protocol, an MMC protocol, a Peripheral Component Interconnection (PCI) protocol, a PCI-Express (PCI-E) protocol, an Advanced Technology Attachment (ATA) protocol, a serial-ATA protocol, a parallel-ATA protocol, a Small Computer Small Interface (SCSI) protocol, an Enhanced Small Disk Interface (ESDI) protocol, an Integrated Drive Electronics (IDE) protocol, and a Firewire protocol.

In some examples, as shown in FIGS. 1 and 2B, FIG. 2B is a structural diagram of the memory system 100 provided by some examples of the present disclosure. The memory system 100 further comprises a transfer layer 20. The chip package structure 10 is electrically connected with the processor 200 through the transfer layer 20. By integrating the chip package structure 10 and the processor 200 on the transfer layer 20, the distance between the chip package structure 10 and the processor 200 may be reduced, and the signal transfer speed between the chip package structure 10 and the processor 200 may be increased.

In an example, the chip package structure 10 and the processor 200 are located over the same side of the transfer layer 20.

In an example, the transfer layer 20 may be a redistribution layer (RDL) fabricated by a redistribution process. The redistribution layer may comprise a plurality of layers of metal wirings and a plurality of dielectric layers. Every two adjacent layers of the metal wirings are spaced apart by the dielectric layer, wherein the dielectric layer may be made of a resin material or other insulation materials. In order to implement an electrical connection between the metal wirings on different layers, a conductive channel may be fabricated in the dielectric layer, such that the metal wirings of the different layers are electrically connected through the conductive channel.

The transfer layer 20 may be an interposer, comprising a substrate, a redistribution layer integrated on the substrate, and a conductive channel extending through the substrate. The conductive channel is electrically connected with the metal wiring in the redistribution layer. For example, when the substrate is a silicon substrate formed using a semiconductor material with a silicon element, the interposer is a Si interposer.

In an example, the transfer layer 20 may be electrically connected with the chip package structure 10 and the processor 200 through bumps 30 respectively.

The above-mentioned chip package structure 10 is described below in detail.

In some examples, with continued reference to FIG. 2B, the chip package structure 10 comprises a stack structure D. The stack structure D comprises a plurality of dies 1 that are stacked.

It is to be noted that the die 1 involved in various examples of the present disclosure is a device after wafer cutting and testing without packaging. There are pads for packaging on such a die 1, such that the die 1 cannot be directly applied in an actual circuit. After the die 1 is packaged into a semiconductor chip, it can be applied in the actual circuit.

The example as shown in FIG. 2B makes an illustration by taking the stack structure D comprising 4 dies 1 as an example. However, the number of the dies 1 in the stack structure D is not limited thereto. The number of the dies 1 in the stack structure D may be set according to actual demands. For example, the number of the dies 1 in the stack structure D may be 2, 3, 5, 6, 7, 8, etc.

In an example, with continued reference to FIG. 2B, the stacking of the plurality of dies 1 in the stack structure D may be 3D vertical stacking, which can reduce a package size of the chip package structure 10, facilitate minimization of the chip package structure 10, and increase an integration level of the chip package structure 10.

In an example, the die 1 may comprise a NAND flash memory die, a dynamic random access memory (DRAM) die and a static random access memory (SRAM) die, etc. On the basis that the die 1 is a memory die, a storage density of the single chip package structure 10 can be increased by stacking the plurality of dies 1 in the single chip package structure 10. Compared with a single die 1, the increase in the number of the dies 1 will accordingly increase the storage capacity.

When the die 1 is a dynamic random access memory (DRAM) die, the chip package structure 10 may be a High Bandwidth Memory (HBM). The High Bandwidth Memory (HBM) is a high-performance random access memory (RAM) in which the DRAM dies are 3D stacked. It is usually used in conjunction with a high-performance graphics accelerator and a network device accessing a large dataset. The high bandwidth memory (HBM) can usually achieve higher bandwidth, and meanwhile use less power in a smaller shape parameter.

In some examples, with continued reference to FIG. 2B, the plurality of dies 1 comprise at least one first die 1a and at least one second die 1b.

In an example, the plurality of dies 1 may comprise one first die 1a, or may comprise a plurality of first dies 1a, for example, two first dies 1a, three first dies 1a, four first dies 1a or five first dies 1a, etc.

The plurality of dies 1 may comprise one second die 1b, or may comprise a plurality of second dies 1b, for example, two second dies 1b, three second dies 1b, four second dies 1b or five second dies 1b, etc.

In an example, the first die 1a comprises a qualified die 1, and the second die 1b comprises a defective die 1.

The above-mentioned “defective die 1” means that the die 1 has a defect due to multiple different reasons and thus cannot achieve normal functions.

For example, the reasons causing the defect to the die 1 may be mechanical shock or stress, etc.

For another example, the reasons causing the defect to the die 1 may be also contamination, over temperature or over voltage, etc. In some examples, with continued reference to FIG. 2B, the chip package structure 10 further comprises a buffer die 8. The buffer die 8 is disposed over a side of the stack structure D, and electrically connected with the die 1 in the stack structure D.

In an example, the buffer die 8 may comprise a logic die, a base die, etc.

In an example, the buffer die 8 may achieve several logic functions. The buffer die 8 may comprise a circuit region. The circuit region may be a region including a wafer and a circuit provided by elements formed on the wafer. Some circuits may constitute a physical layer circuit. When the physical layer circuit is a transmitting circuit, the physical layer circuit may be configured as a driver. When the physical layer circuit is a receiving circuit, the physical layer circuit may be configured as a buffer. The circuit region may be formed by silicon, etc.

In an example, with continued reference to FIG. 2B, the die 1 in the stack structure D may be electrically connected with the buffer die 8 through a conductive structure 2 (e.g., an electrical connector, etc.).

The above-mentioned conductive structure 2 may comprise for example one or more through silicon vias (TSVs). The through silicon via (TSV) has the advantages of high density and short vertical interconnect distance, which facilitates increasing a data transfer speed between the die 1 in the stack structure D and the buffer die 8.

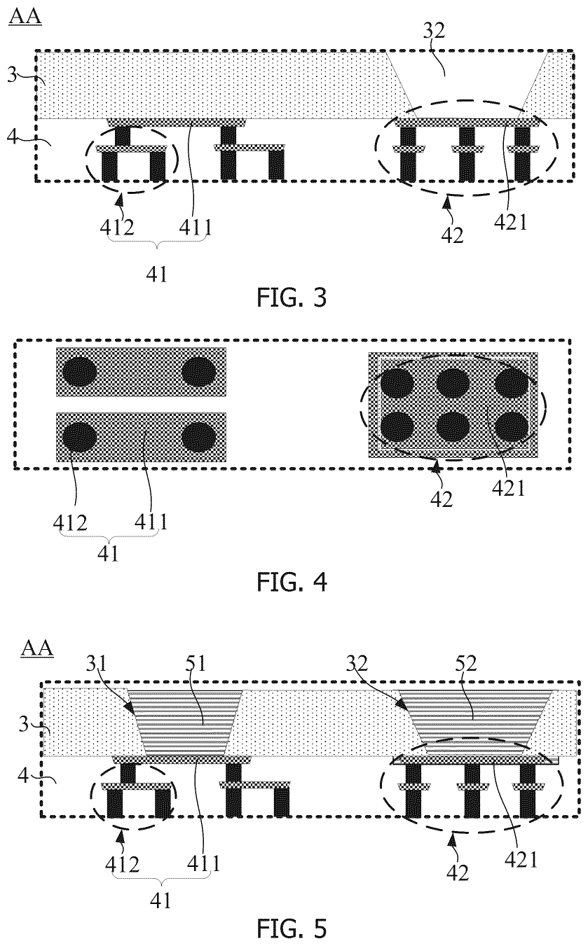

In some examples, as shown in FIGS. 2B and 3, FIG. 3 is a structural diagram of an AA region of the chip package structure 10 in FIG. 2B. The chip package structure 10 further comprises a routing layer 4. The routing layer 4 is located over a side of the stack structure D. A plurality of interconnect structures 41 are disposed in the routing layer 4, and any two of the dies 1 in the stack structure D are connected with each other through at least one of the interconnect structures 41.

In an example, as shown in FIGS. 3 and 4, FIG. 4 is a structural plan view of the routing layer 4 in FIG. 3. The interconnect structure 41 comprises a first conductive pad 411 and at least two connection structures 412. One end of each of the at least two connection structures 412 is connected with the first conductive pad 411, and the other end of each of the at least two connection structures 412 is connected with different ones of the dies 1 respectively.

For example, when the interconnect structure 41 comprises two connection structures 412, one end of each of the two connection structures 412 is connected with the first conductive pad 411, the other end of one of the two connection structures 412 is connected with the first die 1a, and the other end of the other one of the two connection structures 412 is connected with the second die 1b. For example, the first die 1a and the second die 1b in the stack structure D are connected with each other through the interconnect structure 41.

The above-mentioned connection structure 412 may comprise pads, conductive pillars and leads, etc. For example, the connection structure 412 may be formed as a multi-layer or single-layer structure. When the connection structure 412 is formed as a multi-layer structure, the connection structure 412 may comprise pads and conductive pillars. When the connection structure 412 is formed as a single-layer structure, the connection structure 412 may comprise pads, conductive pillars or leads, etc. However, this is merely an example, and the method of disposing the connection structure 412 is not limited thereto. Moreover, the number, spacing, arrangement and the like of the connection structure 412 are not subject to specific limitations, but instead can be fully modified by those skilled in the art according to design details.

In some examples, with continued reference to FIGS. 3 and 4, a test structure 42 is further disposed in the routing layer 4, and connected with at least one die 1 in the stack structure D. The test structure 42 may test the performance of the die 1 connected therewith, for example, may be used to test whether the die 1 is a qualified die or a defective die.

In some examples, with continued reference to FIG. 3, the chip package structure 10 further comprises a protective layer 3. The protective layer 3 is located over a side of the routing layer 4 away from the stack structure D. The protective layer 3 may protect the routing layer 4 to prevent the routing layer 4 from external physical or chemical damage.

In an example, the protective layer 3 may comprise a passivation layer. The material of the passivation layer may include an insulation material. For example, the material of the passivation layer may include thermosetting resin (e.g., epoxy resin), thermoplastic resin (e.g., polyimide resin), resin mixed by the thermosetting resin or the thermoplastic resin and an inorganic filler (e.g., an ABF (Ajinomoto Build-up Film)), etc.

In some examples, as shown in FIG. 5, and in conjunction with FIG. 3, FIG. 5 is a structural diagram of an AA region of the chip package structure 10 in FIG. 2B. A second filling block 52 is disposed in the protective layer 3. The second filling block 52 is located over a side of the test structure 42 away from the stack structure D, and extends through the protective layer 3 along a stacking direction.

Since the second filling block 52 is located in the protective layer 3, before forming the second filling block 52 in the protective layer 3, a second opening 32 is formed for placing the second filling block 52 in the protective layer 3. Since the second filling block 52 extends through the protective layer 3 along the stacking direction, the second opening 32 also extends through the protective layer 3 along the stacking direction. Moreover, since the second filling block 52 is located over a side of the test structure 42 away from the stack structure D, the second opening 32 is also located over the side of the test structure 42 away from the stack structure D.

For example, before forming the second filling block 52 within the second opening 32, the second opening 32 extends through the protective layer 3 along the stacking direction, and located over a side of the test structure 42 away from the stack structure D, which can expose the test structure 42 in the routing layer 4 and facilitates the electrical connection of the test structure 42 and an external device.

In an example, with continued reference to FIG. 3, the second opening 32 exposes the test structure 42 in the routing layer 4, which may be that the second opening 32 exposes a test pad 421 of the test structure 42.

In an example, the second opening 32 may be formed in the protective layer 3 through a laser drilling process. Moreover, residues in the protective layer 3 caused by the laser drilling process may be removed by descum, etching, or other processes.

After forming the stack structure D, the plurality of dies 1 in the stack structure D may be tested by the test structure 42 for analyzing whether the plurality of dies 1 in the stack structure D comprise the second die 1b. If the plurality of dies 1 in the stack structure D comprise at least one second die 1b, the second die 1b is removed. For example, the second die 1b is a defective die, remove the second die 1b is removed in the stack structure D to ensure normal operation of the chip package structure 10.

Due to the difficulty in removing the second die 1b in the stack structure D, it is inconvenient to remove the second die 1b, and during a process of removing the second die 1b, other dies 1 in the stack structure D are prone to damage, resulting in a failure in normal operation of the other dies 1.

On this basis, in some examples, with continued reference to FIG. 5, the chip package structure 10 further comprises a plurality of first filling blocks 51. One of the first filling blocks 51 is located over a side of one of the interconnect structures 41 away from the stack structure D, and the first filling blocks 51 extend through the protective layer 3 along the stacking direction.

Since the first filling block 51 is located in the protective layer 3, before forming the first filling block 51 in the protective layer 3, form a first opening 31 is formed for placing the first filling block 51 in the protective layer 3. Since the first filling block 51 extends through the protective layer 3 along the stacking direction, the first opening 31 also extends through the protective layer 3 along the stacking direction. Moreover, since one of the first filling blocks 51 is located over a side of one of the interconnect structures 41 away from the stack structure D, one of the first openings 31 is also located over the side of one of the interconnect structures 41 away from the stack structure D.

For example, before forming the first filling block 51 within the first opening 31, the first opening 31 extends through the protective layer 3 along the stacking direction, and one of the first openings 31 is located over a side of one of the interconnect structures 41 away from the stack structure D, which may expose the interconnect structure 41 in the routing layer 4.

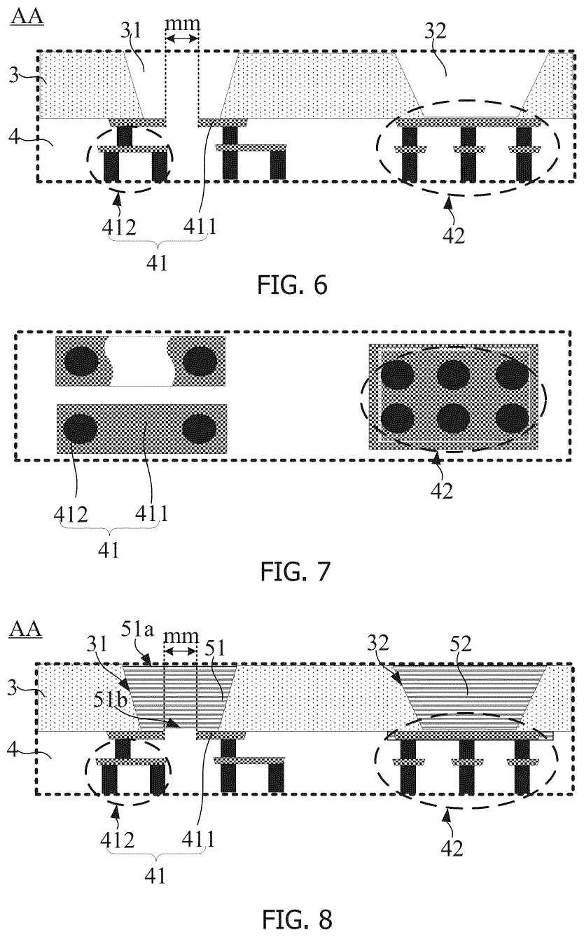

As shown in FIGS. 6, 7 and 8, FIGS. 6 and 8 are structural diagrams of the AA region of the chip package structure 10 in FIG. 2B, and FIG. 7 is a structural plane view of the routing layer 4 in FIG. 6. When the plurality of dies 1 in the stack structure D comprises at least one second die 1b (for example, the second die 1b comprises a defective die 1), the interconnect structure 41 connected with the second die 1b may be broken off via the first opening 31, for example, the second die 1b is broken off from other dies 1 (e.g., the first die 1a) in the stack structure D, such that the second die 1b is in an isolated state. As such, it is not necessary to remove the second die 1b in the stack structure D, the operation is less difficult, and the other dies 1 in the stack structure D, e.g., the first die 1a (e.g., a qualified die), may be prevented from being damaged.

It may be understood that as shown in FIG. 6, since the interconnect structure 41 connected with the second die 1b is broken off via the first opening 31, in the stacking direction, a broken-off region of the interconnect structure 41 overlaps the first opening 31, and there is an overlap region mm.

As shown in FIG. 8, since the first filling block 51 is formed within the first opening 31, in the stacking direction, the broken-off region of the interconnect structure 41 also overlaps the first filling block 51, and there is an overlap region mm.

In an example, with continued reference to FIG. 8, one end of the first filling block 51 away from the routing layer 4 is a first end 51a of the first filling block 51, and one end of the first filling block 51 close to the routing layer 4 is a second end 51b of the first filling block 51.

The area of an end (e.g., the second end 51b of the first filling block 51) of the first filling block 51 close to the routing layer 4 is greater than or equal to the area of the broken-off region of the interconnect structure 41.

For example, as shown in FIG. 8, when the area of an end (e.g., the second end 51b of the first filling block 51) of the first filling block 51 close to the routing layer 4 is greater than the area of the broken-off region of the interconnect structure 41, in the stacking direction, the area of the overlap region mm between the broken-off region of the interconnect structure 41 and the first filling block 51 is less than the area of an end (e.g., the second end 51b of the first filling block 51) of the first filling block 51 close to the routing layer 4.

For another example, when the area of an end (e.g., the second end 51b of the first filling block 51) of the first filling block 51 close to the routing layer 4 is equal to the area of the broken-off region of the interconnect structure 41, in the stacking direction, the area of the overlap region mm between the broken-off region of the interconnect structure 41 and the first filling block 51 is equal to the area of an end (e.g., the second end 51b of the first filling block 51) of the first filling block 51 close to the routing layer 4.

In an example, with continued reference to FIG. 8, the area of an end (e.g., the second end 51b of the first filling block 51) of the first filling block 51 close to the routing layer 4 is less than the area of an end (e.g., the first end 51a of the first filling block 51) of the first filling block 51 away from the routing layer.

In an example, the first opening 31 may be formed in the protective layer 3 through a laser drilling process. Moreover, residues in the protective layer 3 caused by the laser drilling process may be removed by descum, etching, or other processes.

In an example, with continued reference to FIG. 5, the first opening 31 exposes the interconnect structure 41 in the routing layer 4, which may be that the first opening 31 exposes the first conductive pad 411 of the interconnect structure 41.

“The interconnect structure 41 connected with the second die 1b is broken off via the first opening 31” as described above may be specifically that the first conductive pad 411 of the interconnect structure 41 connected with the second die 1b is broken off via the first opening 31.

In an example, the interconnect structure 41 connected with the second die 1b (for example, the second die 1b comprises a defective die 1) is broken off by a laser ablation process.

For example, when the first opening 31 exposes the first conductive pad 411 of the interconnect structure 41, the first conductive pad 411 of the interconnect structure 41 connected with the second die 1b may be broken off through the laser ablation process. The first conductive pad 411 that is broken off has a trace of breaking off by laser ablation.

The above-mentioned “trace of breaking off by laser ablation” may be represented as that, for example, the neighboring region of the position where the first conductive pad 411 breaks off is darker in color compared with other regions of the first conductive pad 411. The above-mentioned “trace of breaking off by laser ablation” may be also represented as that the neighboring region of the position where the first conductive pad 411 breaks off has a curled morphology.

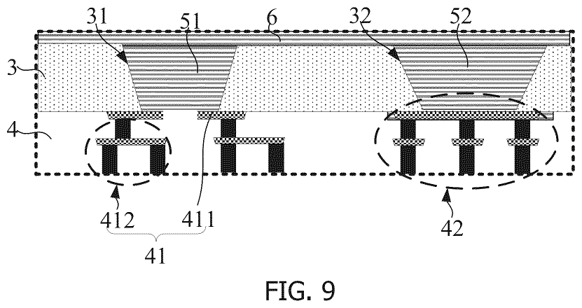

In some examples, as shown in FIG. 9, FIG. 9 is a structural diagram of a partial region of the chip package structure 10 provided by some examples of the present disclosure. The chip package structure 10 further comprises a package layer 6. The package layer 6 covers the stack structure D, the routing layer 4 and the protective layer 3. On the one hand, the package layer 6 can increase the strength of the above-mentioned chip package structure 10; on the other hand, the package layer 6 can also protect the stack structure D, the routing layer 4 and the protective layer 3 in the above-mentioned chip package structure 10, such that the stack structure D, the routing layer 4 and the protective layer 3 are not affected by the external environment (moisture, temperature, contamination, etc.).

In an example, the package layer 6 may comprise epoxy resin, an expansion monomer and a curing agent.

In some examples, with continued reference to FIG. 9, part of material of the package layer 6 forms the first filling block 51 and the second filling block 52, for example, the material for forming the package layer 6 is the same as the material for forming the first filling block 51 and the second filling block 52.

In an example, the package layer 6, the first filling block 51 and the second filling block 52 may have an integral structure.

It is to be noted that the above-mentioned “integral structure” does not mean that the package layer 6 and the first filling block 51 are simply in contact with each other, and the package layer 6 and the second filling block 52 are simply in contact with each other, but instead means that the package layer 6 and the first filling block 51 as well as the package layer 6 and the second filling block 52 are formed integrally (or continuously) with each other using the same material through the same process.

Since the package layer 6 and the first filling block 51 as well as the package layer 6 and the second filling block 52 are formed integrally (or continuously) with each other using the same material through the same process, for example, the first filling block 51 and the second filling block 52 are formed while the package layer 6 is formed, a fabrication process of the chip package structure 10 can be simplified, which facilitates improving the fabrication efficiency of the chip package structure 10.

A fabrication method of the above-mentioned chip package structure 10 is described below in detail.

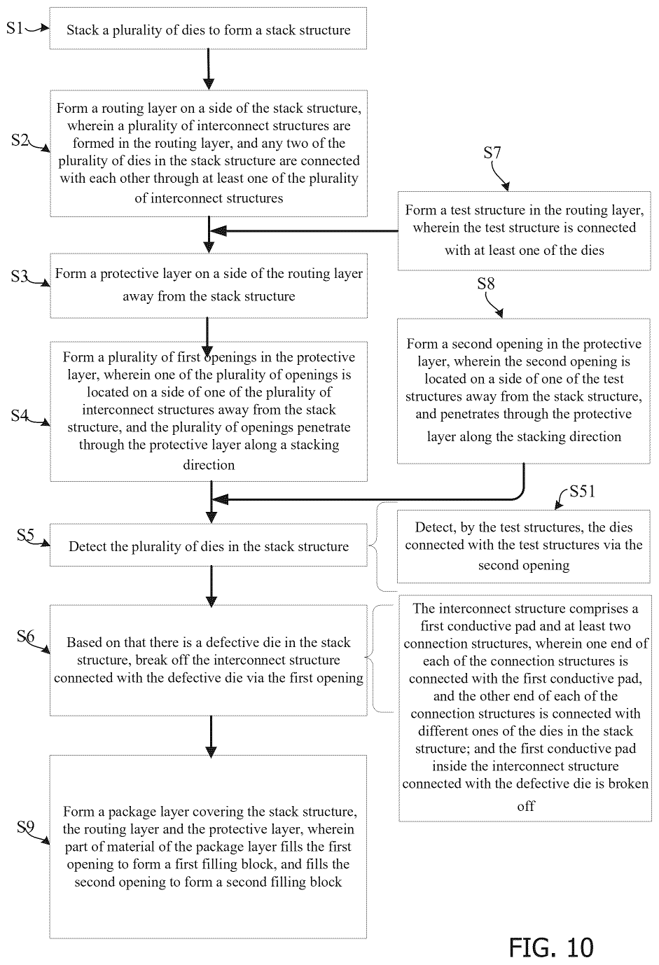

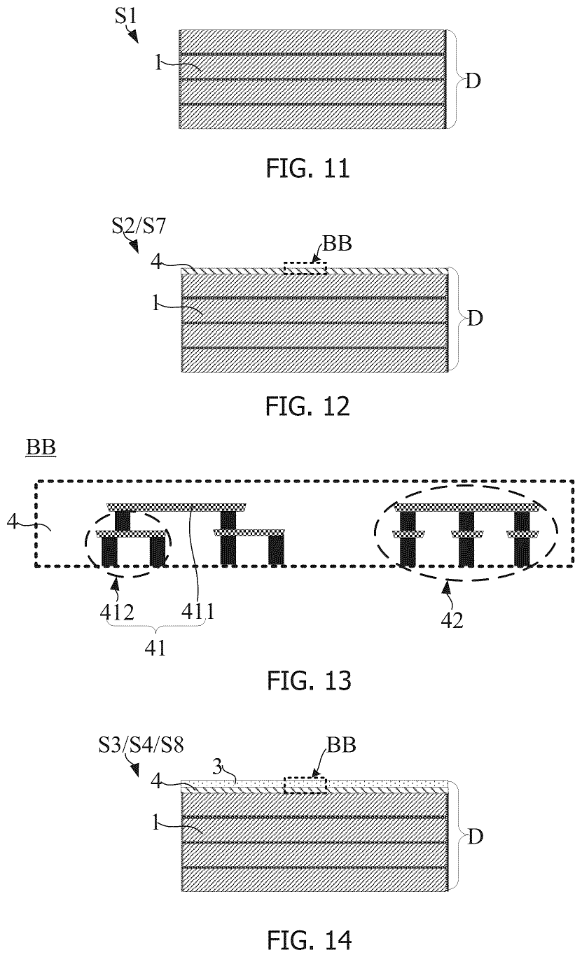

As shown in FIG. 10, FIG. 10 is a flow diagram of the fabrication method of the chip package structure 10 provided by some examples. The fabrication method of the chip package structure 10 comprises:
S1: as shown in FIG. 11, FIG. 11 is a structural diagram corresponding to operation S1 in the fabrication method of the chip package structure 10 provided by FIG. 10. A plurality of dies 1 are stacked to form a stack structure D.
S2: as shown in FIG. 12, FIG. 12 is a structural diagram corresponding to operation S2 and operation S7 in the fabrication method of the chip package structure 10 provided by FIG. 10. A routing layer 4 is formed over a side of the stack structure D.

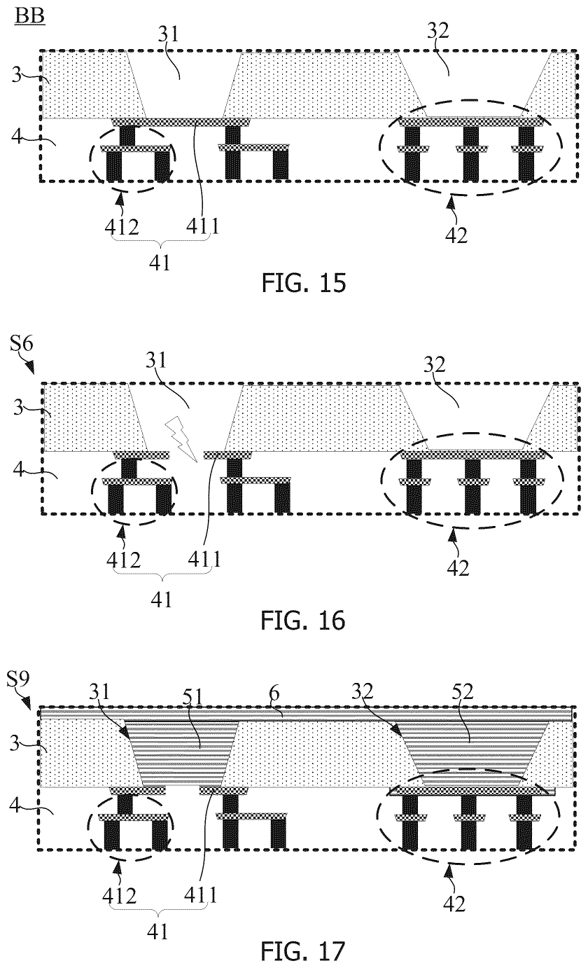

As shown in FIG. 13, FIG. 13 is a structural diagram of a BB region in FIG. 12. A plurality of interconnect structures 41 are formed in the routing layer 4, and any two of the dies 1 in the stack structure D are connected with each other through at least one of the interconnect structures 41.
S7: with continued reference to FIGS. 12 and 13, a test structure 42 is formed in the routing layer 4. The test structure 42 is connected with at least one of the dies 1.
S3: as shown in FIG. 14, FIG. 14 is a structural diagram corresponding to operation S3, operation S4 and operation S8 in the fabrication method of the chip package structure 10 provided by FIG. 10. A protective layer 3 is formed over a side of the routing layer 4 away from the stack structure D.
S4: as shown in FIG. 15, FIG. 15 is a structural diagram of a BB region in FIG. 14. A plurality of first openings 31 are formed in the protective layer 3. One of the first openings 31 is located over a side of one of the interconnect structures 41 away from the stack structure D, and the first openings 31 extend through the protective layer 3 along a stacking direction.
S8: with continued reference to FIGS. 14 and 15, a second opening 32 is formed in the protective layer 3. The second opening 32 is located over a side of the test structure 42 away from the stack structure D, and extends through the protective layer 3 along the stacking direction.
S5: the plurality of dies 1 in the stack structure D are detected.

Based on forming the test structure 42 in the routing layer 4, above-mentioned operation S5 comprises operation S51.
S51: the die 1 connected with the test structure 42 is detected by the test structure 42 via the second opening 32.
S6: as shown in FIG. 16, FIG. 16 is a structural diagram corresponding to operation S6 in the fabrication method of the chip package structure 10 provided by FIG. 10. Based on that there is a defective die 1 in the stack structure D, the interconnect structure 41 connected with the defective die 1 is broken off via the first opening 31.

The plurality of first openings 31 are formed in the protective layer 3, and one of the plurality of first openings 31 is located over a side of one of the interconnect structures 41 away from the stack structure D, and the first openings 31 extend through the protective layer 3 along the stacking direction. When there is a defective die 1 in the stack structure D, the interconnect structure 41 connected with the defective die 1 is broken off via the first opening 31, for example, the defective die 1 is broken off from other dies 1 (e.g., a qualified die 1) in the stack structure D, such that the defective die 1 is in an isolated state. As such, it is not necessary to remove the defective die 1 in the stack structure D, the operation is less difficult, and the other dies 1 (e.g., the qualified die 1) in the stack structure D may be prevented from being damaged.

In an example, above-mentioned operation S4 and operation S8 are performed simultaneously in the same process, for example, the first opening 31 may be compatible with a process of forming the second opening 32, which facilitates simplifying fabrication operations of the chip package structure 10 and reduce fabrication cost of the chip package structure 10.

In an example, with continued reference to FIG. 16, the interconnect structure 41 comprises a first conductive pad 411 and at least two connection structures 412. One end of the connection structure 412 is connected with the first conductive pad 411, and the other end of the connection structure 412 is connected with different ones of the dies 1 in the stack structure D.

In an example, the interconnect structure 41 connected with the defective die 1 may be broken off by a laser ablation process.

For example, the first conductive pad 411 of the interconnect structure 41 connected with the defective die 1 may be broken off through the laser ablation process.

When the interconnect structure 41 connected with the defective die 1 is broken off through the laser ablation process, no additional photomask is needed to add, and the operation is simple, which facilitates reducing the fabrication cost of the chip package structure 10.

In some examples, with continued reference to FIG. 10, the fabrication method of the above-mentioned chip package structure 10 further comprises:

S9: as shown in FIG. 17, FIG. 17 is a structural diagram corresponding to operation S9 in the fabrication method of the chip package structure 10 provided by FIG. 10. A package layer 6 is formed and covers the stack structure D, the routing layer 4 and the protective layer 3.

Part of material of the package layer 6 fills the first opening 31 to form a first filling block 51, and fills the second opening 32 to form a second filling block 52.

For example, the first filling block 51 and the second filling block 52 are formed while the package layer 6 is formed, and the package layer 6, the first filling block 51 and the second filling block 52 may be formed in the same process, which facilitates simplifying fabrication operations of the chip package structure 10 and reducing fabrication cost of the chip package structure 10.

In an example, a process of forming the package layer 6 may be one of a compression molding process, a transfer molding process, a liquid sealant curing molding process, a vacuum lamination process and a spin-coating process.

The above descriptions are merely particular implementations of the present disclosure, and the protection scope of the present disclosure is not limited to those. Any variation or replacement that may be readily figured out by those skilled in the art within the technical scope disclosed by the present disclosure shall be encompassed within the protection scope of the present disclosure. Therefore, the scope of protection of the present disclosure should be defined by the scope of protection of the claims.

What is claimed is:

1. A chip package structure, comprising:
a stack structure comprising a plurality of dies stacked on top of one another;
a routing layer disposed on the stack structure, wherein a plurality of interconnect structures are disposed in the routing layer, and any two of the plurality of dies in the stack structure are connected with each other through at least one of the plurality of interconnect structures;
a protective layer disposed on the routing layer opposite the stack structure; and
a plurality of first filling blocks, wherein one of the plurality of first filling blocks is disposed on one of the plurality of interconnect structures opposite the stack structure, and wherein the plurality of first filling blocks extend through the protective layer along a stacking direction of the chip package structure.

2. The chip package structure of claim 1, wherein the plurality of dies comprise at least a first die and a second die, wherein a first interconnect structure of the plurality of interconnect structures that is connected with the second die is broken off, and wherein along the stacking direction, a broken-off region of the first interconnect structure overlaps the first filling block.

3. The chip package structure of claim 2, wherein the second die comprises a defective die, and wherein the first die comprises a qualified die.

4. The chip package structure of claim 2, wherein the first interconnect structure comprises a first conductive pad and at least two connection structures, first ends of each of the at least two connection structures are connected with the first conductive pad, and second ends of each of the at least two connection structures are connected with different ones of the first and second dies respectively, and wherein the first conductive pad of the first interconnect structure connected with the second die is broken off.

5. The chip package structure of claim 4, wherein the first conductive pad of the first interconnect structure connected with the second die has a trace of breaking off by laser ablation.

6. The chip package structure of claim 2, wherein an area of one end of the first filling block adjacent to the routing layer is greater than or equal to an area of the broken-off region of the first interconnect structure.

7. The chip package structure of claim 1, wherein an area of one end of the first filling block adjacent to the routing layer is less than an area of one end of the first filling block opposite the routing layer.

8. The chip package structure of claim 1, further comprising:
a test structure located in the routing layer and connected with at least one of the plurality of dies; and
a second filling block disposed on the test structure opposite the stack structure and extending through the protective layer along the stacking direction.

9. The chip package structure of claim 8, wherein the chip package structure further comprises a package layer covering the stack structure, the routing layer and the protective layer, and wherein the package layer forms the first filling block and the second filling block.

10. A fabrication method of a chip package structure, comprising:
stacking a plurality of dies to form a stack structure;
forming a routing layer disposed on the stack structure, wherein a plurality of interconnect structures are formed in the routing layer, and any two of the plurality of dies in the stack structure are connected with each other through at least one of the plurality of interconnect structures;
forming a protective layer disposed on the routing layer opposite the stack structure;
forming a plurality of first openings in the protective layer, wherein one of the plurality of first openings is located over a first interconnect structure of the plurality of interconnect structures opposite the stack structure, and the plurality of first openings extend through the protective layer along a stacking direction of the chip package structure;
determining a status of each die of the plurality of dies in the stack structure; and
responsive to identifying a defective die in the stack structure, breaking off, via the first opening, a connection between the first interconnect structure and the defective die.

11. The fabrication method of claim 10, wherein the first interconnect structure is broken off by a laser ablation process.

12. The fabrication method of claim 10, wherein the fabrication method further comprises:
forming a test structure in the routing layer, wherein the test structure is connected with at least one of the plurality of dies; and
forming a second opening in the protective layer, wherein the second opening is disposed on the test structure opposite the stack structure and extends through the protective layer along the stacking direction; and
determining the status of each die of the plurality of dies comprises:
detecting, by the test structure via the second opening, the dies connected with the test structure.

13. The fabrication method of claim 12, further comprising:
forming a package layer that covers the stack structure, the routing layer and the protective layer,
wherein the package layer fills the first opening to form a first filling block and fills the second opening to form a second filling block.

14. The fabrication method of claim 10, wherein the first interconnect structure comprises a first conductive pad and at least two connection structures, first ends of each of the connection structures re connected with the first conductive pad, and second ends of each of the connection structures are connected with different ones of the first and second dies in the stack structure, and wherein breaking off the first interconnect structure connected with the defective die comprises breaking off the first conductive pad of the first interconnect structure connected with the defective die.

15. A memory system, comprising:
a chip package structure, comprising:
a stack structure comprising a plurality of dies stacked on top of one another;
a routing layer disposed on the stack structure, wherein a plurality of interconnect structures are disposed in the routing layer, and any two of the plurality of dies in the stack structure are connected with each other through at least one of the plurality of interconnect structures;
a protective layer disposed on the routing layer opposite the stack structure; and
a plurality of first filling blocks, wherein one of the plurality of first filling blocks is disposed on the plurality of interconnect opposite the stack structure, and wherein the plurality of first filling blocks extend through the protective layer along a stacking direction of the chip package structure; and
a controller connected with the chip package structure.

16. The memory system of claim 15, wherein the plurality of dies comprise at least a first die and a second die, wherein a first interconnect structure of the plurality of interconnect structures that is connected with the second die is broken off, and wherein along the stacking direction, a broken-off region of the first interconnect structure overlaps the first filling block.

17. The memory system of claim 16, wherein the second die comprises a defective die, and wherein the first die comprises a qualified die.

18. The memory system of claim 16, wherein the first interconnect structure comprises a first conductive pad and at least two connection structures, first ends of each of the at least two connection structures are connected with the first conductive pad, and second ends of each of the at least two connection structures are connected with different ones of the first and second dies respectively, and wherein the first conductive pad of the first interconnect structure connected with the second die is broken off.

19. The memory system of claim 18, wherein the first conductive pad of the first interconnect structure connected with the second die has a trace of breaking off by laser ablation.

20. The memory system of claim 16, wherein an area of one end of the first filling block adjacent to the routing layer is greater than or equal to an area of the broken-off region of the first interconnect structure.
